(19) United States
(12) Patent Application Publication
(10) Pub. No.: US 2006/0094194 A1
(43) Pub. Date: May 4, 2006

(54) Advanced disposable spacer process by low-temperature high-stress nitride film for sub-90NM CMOS technology

(75) Inventors: Chien-Hao Chen, Chuangwei Township (TW); Chia-Lin Chen, Judung Jen (TW); Tze-Liang Lee, Hsinchu (TW); Shih-Chang Chen, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/982,115

(22) Filed: Nov. 4, 2004

(51) Int. Cl. H01L 21/336

(52) U.S. Cl. 438/301; 438/303; 438/305

(57) ABSTRACT

A method of forming a semiconductor device comprises providing a gate electrode having exposed side walls formed in a substrate, forming dummy spacers on the gate electrode exposed side walls, performing a first implant to form source and drain implants, forming a capping layer over the gate electrode, the dummy sidewall spacers, and the source and drain, performing a first anneal, and removing the capping layer and the dummy sidewall spacers.

### CROSS-REFERENCE

This application is related to the following commonly-assigned U.S. Patent Application, the entire disclosure of which is hereby incorporated herein by reference:

“A METAL GATE SEMICONDUCTOR DEVICE AND MANUFACTURING METHOD” Attorney Docket No. 24061.165, filed Mar. 25, 2004, having Chien-Chao Huang, Kuang-hsin Chen, and Fu-Liang Yang named as inventors.

### BACKGROUND

An integrated circuit (IC) is formed by creating one or more devices (e.g., circuit components) on a semiconductor substrate using a fabrication process. As fabrication processes and materials improve, semiconductor device geometries have continued to decrease in size. For example, current fabrication processes are producing devices having geometry sizes (or feature size. e.g., the smallest component (or line) that may be created using the process) of less than 90 nm. Scaling progress in fabrication brings in benefits of high integration density and low fabrication cost.

However, the reduction in size of device geometries frequently introduces new challenges that need to be overcome. As microelectronic devices are scaled down to deep submicron, dopant diffusion such as dopant diffusion in the shallow channel of metal-oxide-semiconductor (MOS) transistor during annealing or other high temperature process can change dopant profile and degrade or even fail the device. Furthermore, the electrical efficiency such as carrier mobility may become an issue that impacts device performance.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1 to 9 are sectional views of one embodiment of a microelectronic device during fabrication.

### DETAILED DESCRIPTION

The present disclosure relates generally to semiconductor fabrication and, more specifically, to fabrication of complementary metal-oxide-semiconductor (CMOS) devices.

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

Information Known To The Inventors—Not To Be Considered Prior Art

The following information is known to the inventors and is not considered to be prior art for the purposes of this invention.

Two-step activation annealing techniques by using disposable spacers have been proposed to achieve ultra-shallow, i.e. preferably having a depth of from about 5 to 50 nm and more preferably from about 10 to 30 nm, junction devices leading to high performance. Such disposable spacers are usually formed by CVD SiO₂ but haven't been taken seriously.

Local mechanical strained channel techniques have also been proposed to improve device performance by using high stress contact etch stop SiN layer or a tensile SiO₂ activation capping layer.

Present Invention

In this invention, we propose an advance disposable spacer process combing nitride spacers and nitride capping by a special Si₃N₄ film with low deposition temperature, high tensile stress and high hydrofluoric acid (HF) etch rate for high performance device applications.

Ultra-shallow junctions are formed using 3-step implant (Imp) and a 2-step dopant annealing approach which can allow a higher temperature for source/drain (S/D) annealing and a lower temperature for low-doped-drain (LDD) annealing which provides for good USJ and SCE controllability. A high tensile silicon nitride (Si₃N₄) dummy/real spacer and activation capping layer can effectively enhance tensile strain in device channel to improve device performance. The ultra shallow junction comprises first LDD implants 18, source/drain implants 24, 26 and second LDD implants 34.

Initial Structure—FIG. 1

As shown in FIG. 1, structure 10 includes a gate electrode 14 formed thereover. Gate oxide layer 12 is formed under gate electrode 14.

Structure 10 is preferably a silicon substrate, a silicon-on-insulator (SOI) or a germanium substrate and if more preferably a silicon substrate.

Gate electrode 14 preferably comprises polysilicon (poly), metal, silicide or SiGe and is more preferably polysilicon (poly) as will be used for illustrative purpose hereafter. Gate electrode 14 has a width of preferably from about 10 nm to 10 um and more preferably from about 50 nm to 200 nm. Gate electrode 14 has height of preferably from about 10 nm to 500 nm and more preferably from about 50 nm to 200 nm.

Gate oxide layer 12 preferably comprises silicon oxide, oxynitride, nitrided oxide, nitride and oxide/nitride stack, a high-k dielectric material (i.e. having a dielectric constant (k) of greater than about 3.9) or a multiple film stack and is more preferably silicon oxide. Gate oxide layer 12 has a thickness pf preferably from about 0.5 nm to 20.0 nm and more preferably from about 0.5 nm to 5.0 nm.

As further shown in FIG. 1, a very light low doped drain (LDD) implant 16 is conducted into structure 10 adjacent and outboard of gate electrode 14 to form LDD implants 18 having a depth of preferably from about 5 nm to 50 nm and more preferably from about 10 nm to 30 nm. LDD implant 16 preferably uses As, B, BF₂, In, Xe, Ge, P, Si, F, N, or C atoms and more preferably uses As or B atoms. LDD implants 18 have a dose of preferably from about 1×10¹⁰ to 1×10¹⁶ atoms/cm² and more preferably from about 1×10¹² to 1×10¹⁵ atoms/cm².

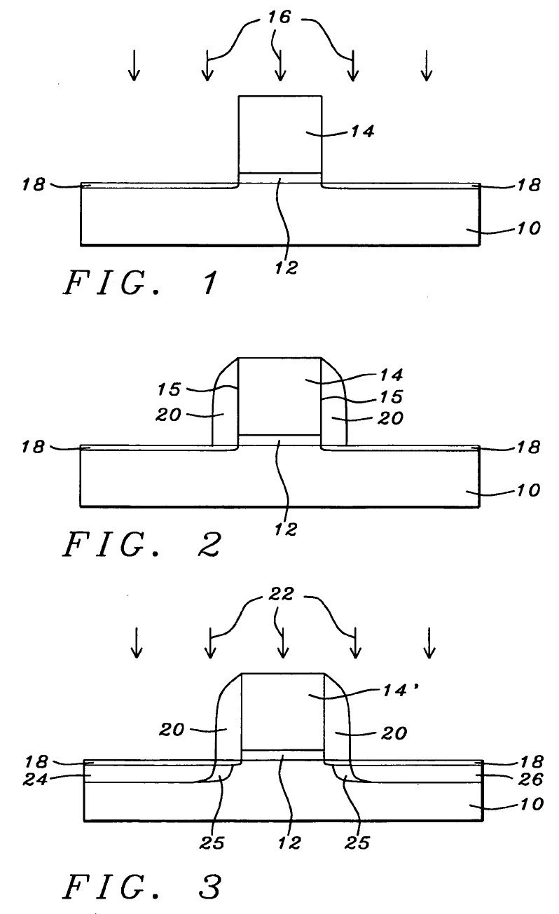

Dummy Sidewall Spacer 20 Formation—FIG. 2

As shown in FIG. 2, dummy sidewall spacers 20 are formed on the exposed side walls 15 of gate electrode 14 to a maximum width of preferably from about 10 nm to 200 nm and more preferably from about 20 nm to 200 nm.

Dummy sidewall spacers 20 preferably comprise silicon nitride (Si₃N₄) (nitride) or a nitride/silicon oxide (SiO₂) (oxide) stack and have a high stress pf preferably from about −2 Gpa to 2 Gpa and more preferably from about 0.5 to 1.5 Gpa.

Dummy sidewall spacers 20 are formed at a low temperature of preferably less than about 600° C. and more preferably from about 350 to 600° C. to prevent dopant diffusion of the LDD implants 18. Dummy sidewall spacers 20 are formed using a precursor of HCD, DCS, BTBAS, DS or SiH₄ with an chemical vapor deposition (CVD)/atomic layer deposition (ALD) tool or using an single wafer (SW) system/furnace. Note that:
a) HCD is Si₂Cl₆;
b) DCS is SiH₂Cl₂;
c) BTBAS is C₈H₂₂N₂Si;
d) DS is Si₂H₆;

Dummy sidewall spacers 20 also have a high HF etch rate of preferably from about 3 nm to 100 nm/minute @ about 1.0% HF @ about room temperature (i.e. about 25° C.) and more preferably from about 5 nm to 80 nm/minute @ about 1.0% HF @ about room temperature so they may be easily removed using an HF dip, for example.

Second, Source/Drain and Pocket, Implant 22,—FIG. 3

As shown in FIG. 3, a second high dose implant 22 is performed into gate electrode 14 and structure 10 adjacent to and outboard of dummy sidewall spacers 20 to form: source and drain implants 24, 26 and pocket implants 25.

Second implant 22 is conducted as a dosage of preferably from 1×10¹¹ to 1×10¹⁶ atoms/cm² and more preferably from about 1×10¹³ to 1×10¹⁶ atoms/cm² preferably using As, B, BF₂ In, F, C, Ge atoms and more preferably As or B atoms. This high dosage implant 22 also coverts poly gate electrode 14 into amorphous poly gate electrode 14′.

Formation of Silicon Nitride Capping Layer 28—FIG. 4

As shown in FIG. 4, a silicon nitride (Si₃N₄) (nitride) capping layer 28 is formed over the structure 10, dummy sidewall spacers 20 and amorphous poly gate electrode 14′ to a thickness of preferably from about 50 to 2000 Å and more preferably from about 100 to 1000 Å. Nitride capping layer 28 has a high stress of preferably form about −2 Gpa to 2 Gpa and more preferably from about 0.5 Gpa to 1.5 Gpa which will enhance the tensile strain in the channel region.

It is noted that the nitride capping layer 28 may also comprise nitride, oxynitride, an nitiride/silicon oxide (SiO2) (oxide) stack, a nitrogen containing film with C, O, B, F, As or Ge dopants, or other highly strained films.

Nitride capping layer 28 is formed using a precursor of HCD, DCS, BTBAS, DS or Si₂H₆. The nitride capping layer may be formed using CVD processing such as low pressure CVD (LPCVD) and plasma enhanced CVD (PECVD), or ALD. For example, silicon nitride capping 28 may be formed using LPCVD/HCD, ALD/DCS, LPCVD/DTBAS, or LPCVD/DS.

This tensile stress of nitride capping layer 28 may be tuned by variations in the formation temperature or gas ratio for specific applications.

Nitride capping layer 28 is formed at a low temperature below the transition temperature of the amorphous poly gate electrode 14, i.e. preferably below about 600° C. and more preferably from about 350 to 600° C. This does little impact on the source/drain 24, 16 profile so this is good for ultra shallow (i.e. having a depth of from about 5 to 50 nm and more preferably from about 10 to 30 nm) junction (USJ) formation.

Nitride capping layer 28 also has a high HF etch rate, i.e. preferably from about 30 to 1000 Å/minute @ about 1.0% HF at about room temperature and more preferably from about 50 to 800 Å/minute @ about 1.0% HF at about room temperature so they may be easily removed using an HF dip as are the dummy spacers 20 as compared to an HF etch rate of about 35 Å/minute for thermal oxide.

The HF etch rate of nitride capping layer 28 (and nitride dummy spacers 20) can be tuned by their respective deposition temperature, pressure and carbon doping. It is noted that a very low HF etch rate may be obtained for the final nitride sidewall spacers 36 (see below).

First Source/Drain 24,26 Anneal 30—FIG. 5

As shown in FIG. 5, a first source/drain 24, 26, anneal 30 is then conducted at a temperature of preferably from about 800 to 1200° C. and more preferably from about 900 to 1100° C. for from about 1 e⁻⁶ to 300 minutes and more preferably from about 1 e⁻⁶ to 10 minutes by furnace, rapid thermal anneal to activate the dopant and enhance stress residual in the channel.

Anneal 30 causes the amorphous poly of the amorphous poly gate electrode 14 to recrystallize which increases the tensile strain in the channel with nitride capping layer 28 enhancing this effect. The stress from the nitride capping layer can be retained in the polysilicon through the recrystallization procedure, thus enhancing the strain in the channel.

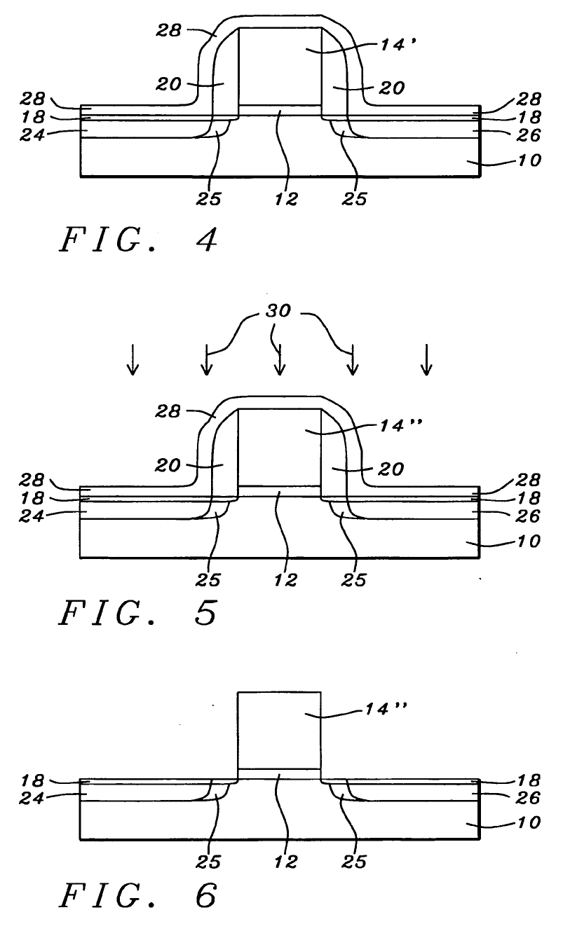

Removal of Nitride Capping Layer 28 and Dummy Spacers 20—FIG. 6

As shown in FIG. 6, the high HF etch rate of both nitride capping layer 28 and dummy spacers 20, that is the high selectivity compared to silicon (Si) and silicon oxide (SiO₂), permits them to be removed directly using an HF dip. A dilute HF can be used for this HF dip process. The ratio of HF:H₂O is preferably from about 1:1000 to about 1:10 depending upon the nitride etch rate. The etch time also depends upon the etch rate of the SiN film.

It is also possible to use H₃PO₄ to remove the nitride capping layer 28 and the dummy spacers 20. An H₃PO₄ removal process may stop on the spacer liner oxide.

Third, Light LDD, Implant 32—FIG. 7

As shown in FIG. 7, a third implant, a light LDD implant, 32 is then conducted to form second LDD implants 34

Second Dopant Activation—FIG. 7

As shown in FIG. 7, a second dopant activation anneal 31 is employed to activate the LDD implants 34 using a lower temperature than used for anneal 30, that is a temperature of preferably from about 600 to 1100° C. and more preferably from about 900 to 1000° C. for preferably from about 1 e⁻⁶ to 300 minutes and more preferably from about 1 e⁻⁶ to 10 minutes by furnace, rapid thermal anneal, spike anneal or laser anneal. This second dopant activation temperature may be lower due to the use of the light LDD implant 32 to form second LDD implants 34 and this lower temperature prevents LDD diffusion. A lower activation temperature is needed for LDD due to it's lower dopant dose.

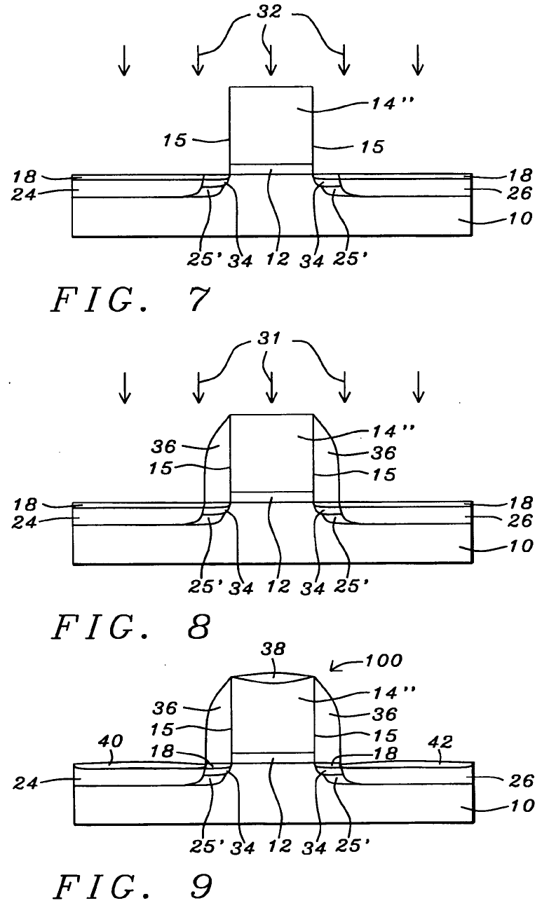

Formation of Final Sidewall Spacers 36—FIG. 8

As shown in FIG. 8, final sidewall spacers 36 are formed on the exposed side walls 15 of recrystallized gate electrode 14″ to a maximum width of preferably from about 50 to 2000 Å and more preferably from about 100 to 1000 Å. Final sidewall spacers 36 are formed at a low temperature of preferably from about 300 to 700° C. and more preferably from about 400 to 600° C.

Final sidewall spacers 36 preferably comprise silicon nitride (Si₃N₄) (nitride) or a nitride/silicon oxide (SiO₂) (oxide) stack. Final sidewall spacers 36 have a low HF etch rate of prevent final sidewall spacer 36 loss by a pre-silicide HF dip (see below). Final sidewall spacers 36 have an HF etch rate of preferably from about 5 to 200 Å/minute and more preferably about less than about 35 Å/minute.

This low HF etch rate can be tuned by temperature, pressure, carbon deposition, etc. The dummy spacers 20 are tuned to have a high etch rate so they may be easily removed while the final sidewall spacers 36 are tuned to have a low etch rate to prevent spacers 36 loss by the subsequent etch step.

Silicide 38, 40 Formation and Further Processing—FIG. 9

As shown in FIG. 9, silicide portions 38, 40 are formed over the exposed portions of recrystallized gate electrode 14″ and source/drain 24, 26, respectively to form the CMOS device 100. Further processing may then proceed.

Advantages of the Present Invention

The advantages of one or more embodiments of the present invention include:

1. disposable dummy sidewall spacers 20 are integrated into the process of the present invention by the utilization of low temperature formation, high-tensile stress property and high HF etch rate property;

2. the three-step implantation and two-step dopant annealing steps of the present invention permit higher temperature for source/drain annealing and a lower temperature for LDD annealing providing for good USJ and SCE controllability;

3. the 450 to 600° C. low temperature formation of the nitride capping layer has little on USJ formation;

4. the high tensile stress of the nitride dummy spacers, final spacers, final spacers and activation capping layer combine to effectively enhance the tensile stress strain in the device channel to improve the device performance; and

5. the HF etch rate of low deposition temperature (LT) nitride can be tuned by carbon doping, precursor gas ratio and/or deposition temperature.

While particular embodiments of the present invention have been illustrated and described, it is not intended to limit the invention, except as defined by the following claims. For example. The disclosed method is not limited to form only CMOS device. The method may be applicable to negative MOS (NMOS), positive MOS (PMOS), single gate transistor, multiple gate transistor, FinFET transistor, silicon on insulator (SOI) structure, and other semiconductor devices.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
providing a gate electrode formed in a substrate, having exposed side walls;
forming dummy spacers on the gate electrode exposed side walls;
performing a first implant to form source and drain;
forming a capping layer over the structure, the dummy sidewall spacers, and the source and drain;
performing a first anneal; and
removing the capping layer and the dummy sidewall spacers.

2. The method of claim 1 further comprising:
performing a second implant to form low doped drain implants after removing the capping layer and the dummy sidewall spacers; and
performing a second anneal after performing the second implant.

3. The method of claim 1 further comprising forming another implant before forming dummy spacers and after providing the gate electrode.

4. The method of claim 1 further comprising forming final sidewall spacers on the gate electrode exposed side walls to form the semiconductor device.

5. The method of claim 1 wherein the semiconductor device includes a junction having a depth between about 5 nm and about 50 nm.

6. The method of claim 1 wherein the dummy spacers and the capping layer are each formed at a temperature of less than about 600° C.

7. The method of claim 1 wherein the dummy spacers and the capping layer are each formed at a temperature between about 350° C. and 600° C.

8. The method of claim 1 wherein the dummy spacers and the capping layer comprises silicon nitride or silicon nitride/silicon oxide stack.

9. The method of claim 1 wherein the dummy spacers and the capping layer each have a stress between about −2 Gpa and about 2 Gpa.

10. The method of claim 1 wherein the dummy spacers and the capping layer each have a stress between about 0.5 Gpa and about 1.5 Gpa.

11. The method of claim 1 wherein the dummy spacers are removed at an etch rate between about 3 nm and about 100 nm per minute using about 1% hydrofluoric acid (HF) at about room temperature.

12. The method of claim 1 wherein the dummy spacers are removed at an etch rate between about 5 nm and about 80 nm per minute using about 1% HF at about room temperature.

13. The method of claim 1 wherein the dummy spacers has an etch rate between about 3 nm and about 100 nm per minute in 1% HF solution and at about room temperature; the capping layer has an etch rate between about 30 nm and about 1000 nm per minute in 1% HF solution and at about room temperature.

14. The method of claim 1 wherein the first anneal is conducted at a temperature of from about 800 to 1200° C. and the second anneal is conducted at a temperature of from about 600 to 1100° C.

15. A method of forming a semiconductor device, comprising:
providing a gate electrode having exposed side walls;
performing a first implant to form first low doped drain implants adjacent and outboard of the gate electrode;
forming dummy spacers on the gate electrode exposed side walls;
performing a second implant to form source and drain;
forming a capping layer over the gate electrode, the dummy sidewall spacers and the gate electrode;
performing a first anneal;
removing the capping layer and the dummy sidewall spacers;
performing a third implant to form second low doped drain implants;
performing a second anneal; and
forming final sidewall spacers on the gate electrode exposed side walls to form the semiconductor device, having a junction having a depth ranging from about 5 nm to about 50 nm.

16. The method of claim 15, wherein the dummy spacers and the capping layer each comprises silicon nitride formed at a temperature of less than about 600° C.

17. The method of claim 15, wherein the dummy spacers comprise silicon nitride of silicon nitride or a silicon nitride/silicon oxide stack.

18. The method of claim 15, wherein the dummy spacers and the capping layer each have a stress of from about −2 G to about 2 Gpa.

19. The method of claim 15, wherein the dummy spacers are removed at an etch rate of from about 3 nm to about 100 nm per minute using about 1% HF at about room temperature.

20. The method of claim 15, wherein: the dummy sidewall spacers has an about 1.0% HF etch rate of from about 3 nm to 100 nm/minute at about room temperature; the capping layer has an about 1.0% HF etch rate of from about 30 to 1000 Å/minute at about room temperature;
and the final sidewall spacers have an HF rate of from about 5.0 to 200.0 Å/minutes.

21. The method of claim 15, wherein the first anneal is conducted at a temperature of from about 800° C. to about 1200° C. and the second anneal is conducted at a temperature of from about 600° C. to about 1100° C.

22. A method of forming a metal-oxide-semiconductor (MOS) device, comprising the steps of:
providing a gate electrode having exposed side walls;
performing a first implant to form first low doped drain implants;
forming dummy spacers on the gate electrode exposed side walls, wherein the dummy sidewall spacers have an about 1.0% HF etch rate of from about 3 m to 100 nm/minute at about room temperature;
performing a second implant to form source and drain;
forming a capping layer over the gate electrode, the dummy sidewall spacers, and the source and drain; the capping layer having an about 1.0% HF etch rate of from about 30 to about 1000 Å/minute at about room temperature;
performing a first anneal;
removing the capping layer and the dummy sidewall spacers;
performing a third implant to form second low doped drain implants;
performing a second anneal; and
forming final sidewall spacers on the gate electrode exposed side walls to for the MOS device; the final sidewall spacers having an HF rate from about 5.0 to 200.0 Å/minutes.

23. The method of claim 22, wherein the MOS device includes a junction having a depth of from about 5 to 50 nm.

24. The method of claim 22, wherein the dummy spacers comprise silicon nitride or a silicon nitride/silicon oxide stack.

25. The method of claim 22, wherein the dummy spacers have a stress of from about −2 Gpa to about 2 Gpa.

26. The method of claim 22, wherein the first anneal is conducted at a temperature of from about 800° C. to about 1200° C. and the second anneal is conducted at a temperature of from about 600° C. to about 1100° C.
